(19) United States
(12) Patent Application Publication
(10) Pub. No.: US 2003/0202332 A1
(43) Pub. Date: Oct. 30, 2003

(54) Second level packaging interconnection method with improved thermal and reliability performance

(76) Inventors: Tommi Reinikainen, Coppell, TX (US); Pirkka Myllykoski, Helsinki (FI)

Correspondence Address: STEVEN A. SHAW, NOKIA, INC., 6000 CONNECTION DRIVE, MD 1-4-755, IRVING, TX, 75039, US

(21) Appl. No.: 10/393,238

(22) Filed: Mar. 20, 2003

Related U.S. Application Data
(60) Provisional application No. 60/376,133, filed on Apr. 29, 2002.

(51) Int. Cl. H05K 7/10; H05K 7/12

(52) U.S. Cl. 361/767

(57) ABSTRACT

Surface mount packages having a plurality of polymer and metallic contacts (e.g., balls) applied thereon and methods of fabricating and utilizing such packages are provided. The polymer balls are employed to improve mechanical compliance of the package; and the metallic (e.g., copper) balls are employed to improve thermal conduction between the package and a substrate to which the package is attached. The polymer balls can be located on a periphery portion of a package where mechanical and thermal stresses are the highest; and the metallic balls can be located on a middle portion of the package. Thus the present invention improves both mechanical stresses and thermal conductivity of a second level packaging interconnection, which in turn improves reliability of an electronic device.

### CROSS-REFERENCE TO RELATED APPLICATION

This application claims priority under 35 U.S.C. 119(e) to provisional application U.S. Serial No. 60/376,133 filed on Apr. 29, 2002.

### BACKGROUND OF THE INVENTION

The present invention relates to second level packaging and, more particularly, to methods of fabricating and utilizing second level interconnects with improved thermal and reliability performance.

Microelectronic devices contain millions of electrical circuit components, mainly transistors assembled in integrated circuit (IC) chips, but also resistors, capacitors, and other components. These chips are mounted on carriers or substrates, such as printed wiring boards, which physically support the chips and electrically interconnect the chips with other elements of the circuit. The interconnection between the chip itself and its supporting substrate is commonly referred to as a “first level” assembly or chip interconnection. This is distinguished from the interconnection between the substrate and larger elements of the circuit, which is commonly referred to as a “second level” interconnection.

The first level interconnection structures connecting a chip to a substrate are typically subject to substantial stresses caused by thermal cycling as temperatures within the device change during operation. Electrical power dissipated within the chip tends to heat the chip as well as the substrate, such that temperature of the chip and substrate rises when the device is turned on and falls when the device is inactivated. As the chip and substrate ordinarily are formed from diverse materials having differing coefficients of thermal expansion (CTE), the chip and substrate ordinarily expand and contract by different amounts. This causes electrical contacts on the chip to move relative to electrical contact pads on the substrate as the temperature of the chip and substrate changes. The relative movement deforms the electrical interconnections between the chip and substrate and places them under mechanical stress, which can cause breakage of the electrical interconnections. Thermal cycling stresses may also occur where the chip and substrate are formed from like materials having similar CTEs, as the temperature of the chip may increase more rapidly than the temperature of the substrate when power is first applied to the chip.

Interconnect reliability is an important issue that affects total reliability of an electronic device. Wireless devices can place high demands for solder interconnects due to rough usage conditions. For example, wireless devices may experience high impact shocks due to drop of the device, and other mishandling. In addition, miniaturization of wireless devices drives for miniaturization of electronics and accordingly, electrical interconnects. Thus, mechanical strength of the electrical interconnects is potentially decreased. Furthermore, die shrink, e.g., diminishing of a Silicon (Si) chip due to advances in wafer processes, results in higher temperatures on the IC chip when power levels remain the same.

Certain designs have been directed to reducing problems associated with thermal cycling by redistributing thermal cycling stresses into an underfill layer to decrease the CTE mismatch. Typically, the underfill layer includes an elastomeric layer which, in the finished package, is disposed between the chip carrier and the face surface of the chip. The underfill layer provides resiliency to the individual terminals, allowing the terminals to move in relation to their electrically connected chip contacts to accommodate CTE mismatch as necessary during testing, final assembly, and thermal cycling of the device. However, the underfill process adds cost, affects re-workability, and increases production line length. Furthermore, it has been noticed that underfill materials may have negative effects on health of production personnel.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor delineate the scope of the invention. Its sole purpose is to present some concepts of the invention in a simplified form as a prelude to the more detailed description that is presented later.

The present invention relates to systems and methods for second level packaging interconnections with improved thermal and reliability performance. Interconnect reliability can be a life-limiting factor of an electronic device. Thus, in accordance with an aspect of the present invention, a surface mount package is provided having a plurality of polymer contacts (e.g., polymer balls) to improve mechanical compliance of the package. The surface mount package further includes a plurality of metallic contacts (e.g., copper balls) to improve thermal conduction between the package and a substrate to which the package is attached. The polymer contacts can be located on a periphery portion of a package where mechanical and thermal stresses are the highest; and the metallic contacts can be located on a middle portion of the package. The present invention has applicability to systems and methodologies associated with electronic applications where electrical or thermal conductivity is required between two surfaces and/or where a controlled thickness bond line is required.

To the accomplishment of the foregoing and related ends, certain illustrative aspects of the invention are described herein in connection with the following description and the annexed drawings. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 illustrates a cross sectional side view of an electronic component with a plurality of polymer contacts and a plurality of metallic contacts in accordance with an aspect of the present invention.

FIG. 2 illustrates a copper and solder coated polymer ball in accordance with an aspect of the present invention.

FIG. 3 illustrates a solder coated copper ball in accordance with an aspect of the present invention.

FIG. 4 illustrates a top view of an electronic component having a plurality of polymer contacts and metallic contacts in accordance with an aspect of the present invention.

FIG. 5 illustrates a top view of another electronic component having a plurality of polymer contacts and metallic contacts in accordance with an aspect of the present invention.

FIG. 6 illustrates a top view of another electronic component having a plurality of polymer contacts and metallic contacts in accordance with an aspect of the present invention.

FIG. 7 illustrates a cross sectional side view of a surface mount package attached to a substrate in accordance with an aspect of the present invention.

FIG. 8 illustrates different configurations of polymer and metallic cores in accordance with an aspect of the present invention.

FIG. 9 illustrates a methodology for fabricating a surface mount package having a plurality of polymer contacts and metallic contacts in accordance with an aspect of the present invention.

Fig. 10 illustrates a methodology for attaching a surface mount package having a plurality of polymer contacts and metallic contacts to a substrate in accordance with an aspect of the present invention.

### DETAILED DESCRIPTION OF INVENTION

The present invention relates to second level packaging in electronics, e.g., interconnects between a package, containing an IC chip, such as an Application Specific Integrated Circuit (ASIC), a memory, or any combination of chips, and a printed wiring board; and will now be described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block form in order to facilitate describing the present invention.

Second level packaging involves integrated circuit packages and other components being assembled onto substrates, such as printed wiring boards and ceramic substrates. The integrated circuit is generally located in a middle portion of the package and the remainder of the package is employed to distribute input and output devices. Solder balls can be employed to facilitate connection of the integrated circuit packages with the printed circuit boards. Such interconnections are generally referred to as area array interconnections and can be included in packages, such as flip-chip, ball grid array (BGA), and chip scale packages (CSP). Near-eutectic (e.g., Sn63PB37) solder balls are commonly employed to facilitate the connection; however, several other compositions of solder balls are possible. For example, polymer balls having copper and solder coating can improve reliability of interconnects. However, employing polymer solder balls can result in poor thermal performance of the polymer material. Due to increased data rates and functionality of wireless devices, power dissipation of ASICs, etc. increases significantly, and an efficient thermal path is needed from the integrated circuit to the system.

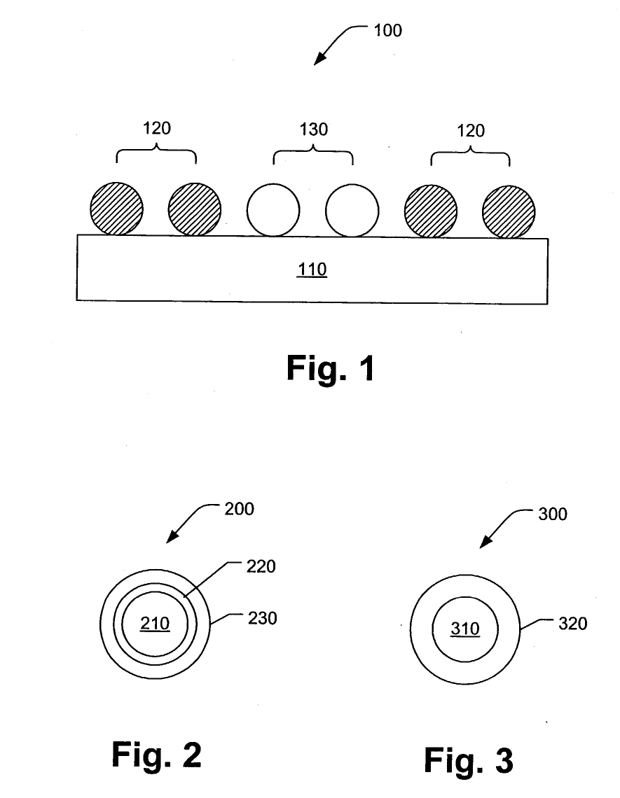

FIG. 1 illustrates a cross sectional side view of a surface mount package 100 in accordance with an aspect of the invention. The surface mount package 100 comprises an electronic component 110, a plurality of polymer contacts (e.g., polymer balls) 120, and a plurality of metallic contacts (e.g., copper balls) 130. Although the present invention is primarily described with the respective contacts being balls, it is to be appreciated that any suitable form for the contacts may be employed in connection with the present invention and such forms are intended to fall within the scope of the hereto appended claims. The plurality of polymer balls 120 and metallic balls 130 are employed as attachment material for the surface mount package 100 to facilitate connection of the package 100 to a substrate, such as a printed wiring board (not shown). The polymer balls 120 and metallic balls 130 are employed to improve reliability of an electronic device, as the reliability of the electronic device is largely affected by joint reliability. The polymer balls 120 improve mechanical compliance of the surface mount package 100 to the substrate. However, as stated above, polymer balls generally have poor thermal performance. Thus, metallic balls 130 are also included on the package 100 to improve thermal conduction from the package 100 to the substrate. Accordingly, the surface mount package 100 improves both mechanical stresses and thermal conductivity of the interconnection, which leads to improved joint reliability and thus, improved total reliability of the electronic device.

Turning now to FIGS. 2 and 3, examples of compositions of a polymer ball 200 and a metallic ball 300 which can be employed are illustrated. The polymer ball 200 includes a polymer core 210 of a size suitable for a desired application, coated with a copper layer 220 and a solder layer 230. The copper and solder layers 220 and 230 are employed to facilitate electrical contact via solder attachment to input/output pads of an integrated circuit element (not shown). The metallic ball 300 includes a solid metallic core 310 (e.g., copper) and is also coated with a solder layer 320 to facilitate electrical contact with the integrated circuit. The solder coating 230 and 320 on the polymer and metallic balls 200 and 300 acts as a mechanical bond to hold the balls 200 and 300 in electrical contact with interconnecting surfaces of the integrated circuit element, as well as maintains a substantially oxide-free surface until interconnection. The exaggerated size of the package, particularly the polymer and metallic balls, the copper and solder layers, and the thickness of the die, is shown for illustration purposes only and one skilled in the art could readily determine appropriate sizes and amounts of polymer, copper, and solder for carrying out the subject invention with respect to particular packages.

The solder in the solder coated balls can be an alloy of at least two metals selection from the group including tin, bismuth, nickel, cobalt, cadmium, antimony, indium, lead, silver, gallium, aluminum, germanium, silicon, gold, etc. Solder alloys can be eutectic or non-eutectic alloys. Further, there is a trend in the industry to limit the utilization of lead in manufactured products, due to the toxicity of lead. Thus, the surface mount packages of the present invention can be employed having interconnects with lead free polymer and copper cores coated with lead free solder.

It is to be appreciated that flux coated polymer and/or flux coated metallic balls can also be employed. A polymer and/or metallic ball coated with a tacky flux can be printed in place on a substrate and stored for future reflow without degradation. The flux surrounding the ball maintains a substantially oxide free surface and provides surface activation for reflow when an interconnect joint is formed. Thus, flux-coated balls can be employed in flip-chip, ball grid array, fine pitch surface mount applications and the like.

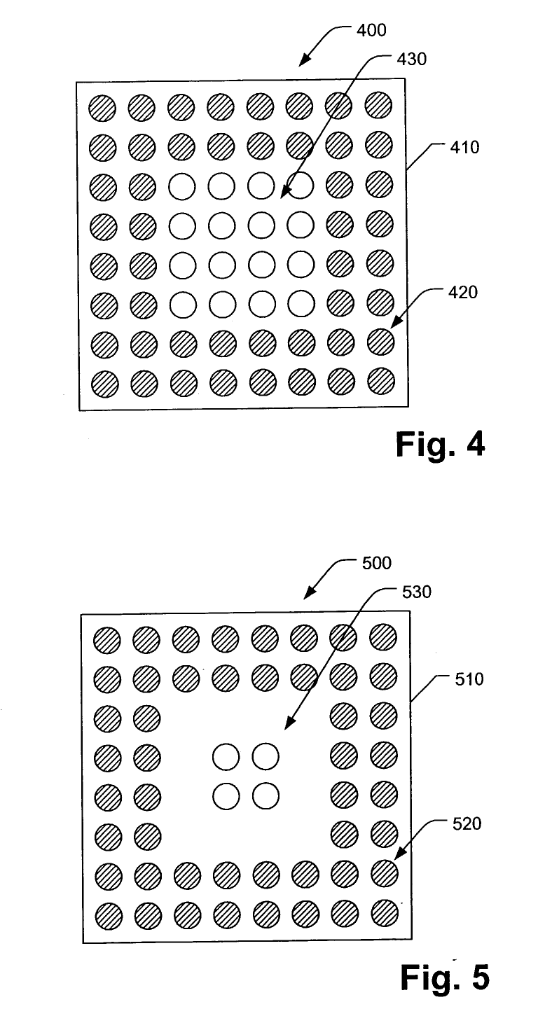

A top view of a surface mount package 400 in accordance with an aspect of the present invention is illustrated in FIG. 4. The surface mount package 400 has an electronic component 410, a plurality of polymer balls 420, and a plurality of solid copper balls 430. The polymer balls 420 are located around a periphery portion of the component 410. This portion is where mechanical and thermal stresses are highest and thus, might create potential liability risks. Thus, the polymer balls 420 are employed in this area to improve the reliability of interconnects by improving mechanical compliance of a solder joint. The solid copper balls 430 are located in a middle portion of the component 410. The solid copper balls 430 are employed to improve thermal conduction from the component 410 when attached to a substrate, e.g., printed wiring board (not shown). The high melting temperature of the copper further facilitates improved standoff, which will be described in greater detail below.

The polymer balls 420 can be coated with copper and solder layers and the copper balls 430 can be solder coated to facilitate electrical contact via solder attachment to the substrate. The solder acts as securing material to facilitate the package 400 being attached (e.g., electrically connected) to the substrate. Although the solder balls are depicted in a substantially uniform, grid-like pattern throughout the figures, it is to be appreciated that the solder balls can be arranged in any pattern. Furthermore, it is to be appreciated that although the subject invention is described with respect to solder balls, the subject invention is not intended to be limited to such types of contacts. Thus, any type(s) of electrical contacts suitable for implementation in accordance with the subject invention are contemplated and are intended to fall within the scope of the hereto appended claims.

FIG. 5 illustrates another example of a surface mount package 500. The package 500 includes an electronic component 510 with a plurality of polymer balls 520 located around a periphery portion of the component 510. The polymer balls 520 can be copper and solder coated or the polymer balls 520 can be coated with any other suitable material to facilitate electrical connection with a substrate. The electronic component 510 also includes a plurality of copper balls 530 located in a middle portion of the component 510. Similar to the polymer balls 520, the copper balls 530 can be solder coated or coated with any other suitable material to facilitate electrical connection with the substrate.

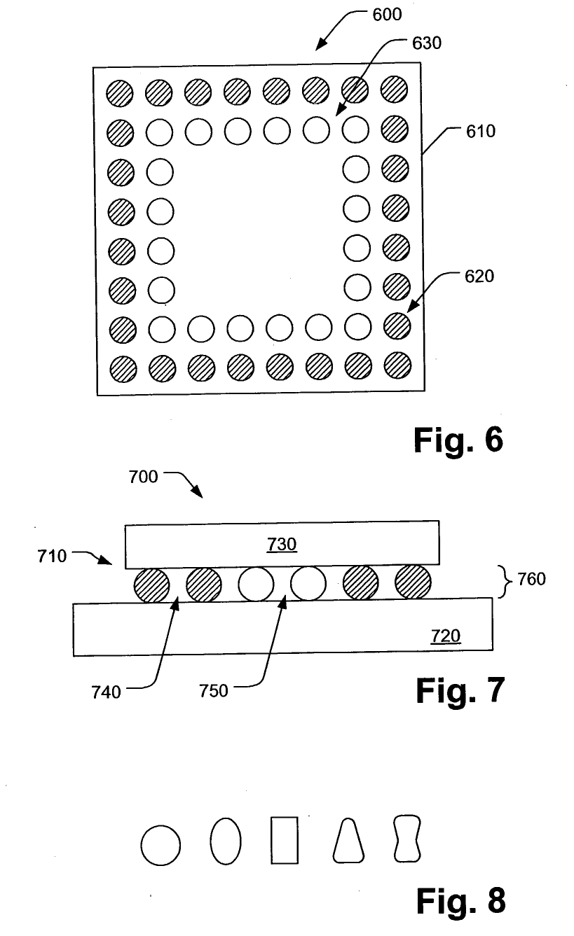

FIG. 6 illustrates yet another example of a surface mount package 600 in accordance with an aspect of the invention. In FIG. 6, the package 600 includes an electronic component 610 with a plurality of polymer balls 620 located around an outer periphery portion of the component 610. The package 600 also includes a plurality of copper balls 630 located around an inner periphery portion of the component 610. The polymer and copper balls 620 and 630 can be coated with any suitable material to facilitate electrical connection with a substrate.

The examples above have been illustrated with polymer balls situated around a periphery portion of an electrical component and copper balls located in a middle portion of the component. However, it is to be appreciated that the copper balls can also be included in the periphery portion and the polymer balls can also be included in the middle portion of the electrical component. Moreover, the solder and copper coated ball pattern has been illustrated to be substantially contiguous around an outer perimeter of a package. However, the solder and copper coated polymer ball pattern can also be applied on one or any number of sides of the package.

When a package and substrate assembly is heated and solder reflows, surface tension of the exposed solder facilitates aligning the package into a desired position on the substrate. Once a surface mount package has been assembled, the package is aligned with a substrate such that electrical contacts on the package (e.g., solder ball array) corresponds with components on the substrate. The package is positioned and held onto the substrate by at least one of: placement pressure, heat, or application of other suitable agents. The process of attaching the package to the substrate can be accomplished in several different manners, with or without heat and pressure. Some examples of such methods include: placing the package after solder paste is printed; placing the package without solder paste; applying flux to the substrate, then placing the package; and applying flux to the package prior to placement.

FIG. 7 illustrates an electronic device 700 in accordance with an aspect of the present invention. The electronic device 700 includes a surface mount package 710 attached to a substrate, or printed wiring board 720. The package 710 comprises an electronic component 720 having a solder ball array with polymer balls 730 and solid copper balls 740. The polymer and copper balls 730 and 740 are coated with a layer of solder (not shown) or other suitable attachment material. The package 710 is connected to the substrate 720 through a soldering process, such as heat radiation or conduction, which brings printed circuit assemblies into contact with heated air to melt the solder. Solder reflow is completed in several stages or zones of different temperature. First, the heated air increases board 720 and component 710 temperature, then, activates the flux, and reflows the solder “printed” on the board surface, onto which components have been attached. Upon melting in the highest temperature zone, the solder wets the termination areas and, after cooling, establishes a solder joint. It is to be appreciated that the temperature for the reflow process is controlled such that only the solder coating reflows and not the polymer or copper core.

Common reflow heating methods include infrared radiation, forced hot air convection, and thermal conduction. During an infrared radiation process, radiant infrared energy is absorbed by materials of the device 700 causing the device 700 to heat thus effecting reflow of solder. In a forced hot air convection process, air is heated and circulated in a respective zone. The heat is transferred to the device 700 via the heated air, causing the device 700 and electrical contacts (e.g., solder balls) to heat and cause reflow of the solder. The thermal conduction process involves the device 700 being moved across a surface of a progressive series of heated platen. Heat is transferred through surface contact, allowing the electrical contacts (e.g., solder balls) to heat and reflow.

Further, the copper balls 750 provide a standoff that can produce a controlled gap 760 between the package 710 and the substrate 720. If the gap 760, or interconnect length, is close to zero, any mismatch between the CTE of the package 710 and the CTE of the substrate 720 can cause high stress concentrations. Accordingly, a longer joint mitigates the likelihood of failure at a solder joint under conditions of thermal mismatch. Thus, due to the high melting temperature of the copper balls 750, the copper balls 750 mitigate collapse of the solder during solder reflow, which also mitigates the probability of electrical shorting between unpassivated silicon die edges created during a dicing operation, to solder coating lands. Moreover, the standoff height 760 facilitates effective cleaning of the solder joint after the joint is formed by heating. If effective cleaning is not performed at the solder joint, the residual corrosive materials remaining at the joint after soldering will attack the joint and eventually cause the joint to fail.

Varying sizes of balls can be employed to compensate for stresses due to thermal mismatch between the device 710 and substrate 720. Size variations of the balls can be determined with finite element modeling for the different configurations. In addition, although the polymer and copper cores have been referred to as “balls” and have been illustrated as spheres herein, shapes other than spheres can be employed. FIG. 8 depicts some examples of alternate shapes, which one may deem suitable for a particular application.

Turning back to FIG. 7, the substrate 720 can be of any suitable material while considering factors, such as coefficient of thermal expansion (CTE), conductor resistivity, dielectric constant, dielectric loss tangent, and the thermal conductivity of the material. CTE mismatches between the package 710 and a die (first level interconnect) or printed wiring board 720 (second level interconnect) are factors in a product's reliability. The CTE mismatches generate shear stresses that cause joints to fail. As operational frequencies rise and supply voltages decrease, electrical characteristics of the substrate materials become more important. Some examples of suitable substrate material include ceramics, generally alumina, beryllium oxide and aluminium nitride, and organic laminate-based materials.

An additional benefit of the configurations depicted in the subject application, is that cost savings are realized by mitigating the need for an underfill layer. In many conventional applications, underfill is generally dispensed such that the underfill substantially covers an area within the component-to-substrate gap and, additional underfill is sometimes dispensed along a complete assembly periphery. The underfill layer is needed in conventional applications to absorb stresses created by CTE mismatches. Accordingly, due to the improved mechanical and thermal reliability of the package of the present invention, the need for an underfill layer is mitigated.

It is to be appreciated that the solder ball patterns, package placement methods, heating methods, etc. have been presented herein for sake of illustration and description only. As such, these methods are not intended to be exhaustive or to limit the invention to the methods disclosed.

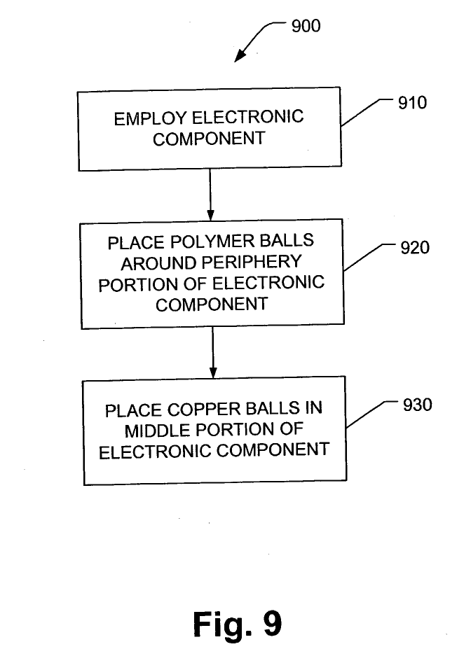

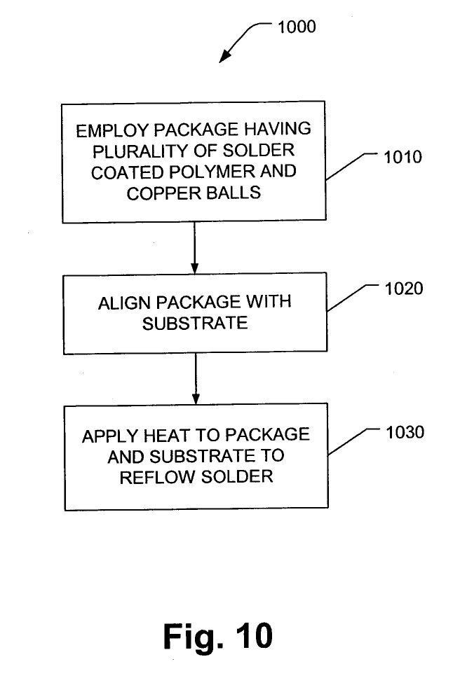

In view of the foregoing structural and functional features described above, methodologies in accordance with various aspects of the present invention will be better appreciated with reference to FIGS. 9-10. While, for purposes of simplicity of explanation, the methodologies of FIGS. 9-10 are illustrated and described as executing serially, it is to be understood and appreciated that the present invention is not limited by the illustrated order, as some aspects could, in accordance with the present invention, occur in different orders and/or concurrently with other aspects from that depicted and described herein. Moreover, not all illustrated features may be required to implement a methodology in accordance with an aspect the present invention.

FIG. 9 illustrates a methodology 900 for fabricating a surface mount package having a plurality of polymer and copper balls. The methodology begins at 910 where an electronic component is employed. Then, at 920, a plurality of copper and solder coated polymer balls are placed around a periphery portion of the electronic component. At 930, a plurality of solder coated copper balls are placed in a middle portion of the electronic component. Thus, the electronic component becomes a surface mount package and can be one of a flip-chip, Ball Grid Array, and Chip Scale Package. The copper and solder coated polymer balls are employed to improve mechanical compliance of the surface mount package when attached to a substrate, while the solder coated copper balls are employed to improve thermal conduction from the surface mount package to the substrate.

FIG. 10 illustrates a methodology 1000 for utilizing a surface mount package having a plurality of polymer and copper balls. This methodology begins at 1010 where a surface mount package having a plurality of solder coated polymer and copper balls is employed. The package is then aligned with a substrate at 1020. Here, the solder coated polymer and copper balls correspond with electrical terminations on the substrate. Then, at 1030, heat is applied to the package and substrate to reflow the solder. During the reflow operation, an electrical connection between the package and substrate is obtained. The combination of polymer and copper coated balls improves reliability of the surface mount package by improving both mechanical compliance and thermal conductivity. Accordingly, the surface mount package of the present invention mitigates the employment of conventional underfill application and curing operations.

It is to be appreciated that the packages and methodologies of the subject invention as described herein have wide applicability. The present invention has applicability to systems and methodologies associated with any electronic application where electrical or thermal conductivity is required between two surfaces and/or where a controlled thickness bond line is required. For example, the interconnection structure of the present invention is applicable to a ball grid array package, a flip-chip assembly, or a chip scale assembly. The present invention can be further employed in fully assembled packages with integrated circuits or to substrates with packages prior to assembly.

What has been described above includes exemplary implementations of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A surface mount package, comprising:
a packaged electronic component;
a plurality of polymer contacts coupled to the packaged electronic component, the plurality of polymer contacts employed to facilitate attachment of the packaged electronic component to a substrate; and
a plurality of metallic contacts coupled to the packaged electronic component, the plurality of metallic contacts employed to facilitate attachment of the packaged electronic component to the substrate.

2. The surface mount package of claim 1, the polymer contacts being polymer balls.

3. The surface mount package of claim 1, the metallic contacts being metallic balls.

4. The surface mount package of claim 3, the metallic balls being copper balls.

5. The surface mount package of claim 1, the plurality of polymer contacts being located around a periphery portion of the packaged electronic component.

6. The surface mount package of claim 1, the plurality of metallic contacts being located in a middle portion of the packaged electronic component.

7. The surface mount package of claim 1, the plurality of polymer contacts being located around an outer periphery portion of the packaged electronic component and the plurality of metallic contacts being located around an inner periphery portion of the packaged electronic component.

8. The surface mount package of claim 1, the plurality of polymer contacts being coated with a layer of copper and a layer of solder.

9. The surface mount package of claim 1, the plurality of metallic contacts being coated with a layer of solder.

10. The surface mount package of claim 1, the plurality of polymer contacts and the plurality of metallic contacts being coated with a flux layer.

11. The surface mount package of claim 1, the plurality of polymer contacts and the plurality of metallic contacts being substantially lead free.

12. A surface mount package comprising:
an packaged electronic component;
a plurality of copper and solder coated polymer balls coupled to the packaged electronic component, the plurality of polymer balls being employed to facilitate attachment of the packaged electronic component to a surface; and
a plurality of solder coated solid copper balls coupled to the packaged electronic component, the plurality of copper balls being employed to facilitate attachment of the packaged electronic component to the substrate.

13. The surface mount package of claim 12, the solder coating of the polymer balls being an alloy composed of at least two of: tin, bismuth, nickel, cobalt, cadmium, antimony, indium, lead, silver, gallium, aluminum, germanium, silicon, gold.

14. The surface mount package of claim 12, the plurality of copper and solder coated polymer balls and the plurality of solder coated solid copper balls being substantially lead free.

15. The surface mount package of claim 12, the plurality of copper and solder coated polymer balls being located around a periphery portion of the packaged electronic component to improve mechanical compliance of the package.

16. The surface mount package of claim 12, the plurality of solder coated solid copper balls being located in a middle portion of the packaged electronic component to improve thermal conduction of the package.

17. The surface mount package of claim 12, the plurality of solder coated solid copper balls employed to mitigate collapse of the solder coating during a reflow process.

18. A method for fabricating a surface mount package, comprising:
employing a packaged electronic component having a first side and a second side;
applying a plurality of polymer contacts to the first side of the packaged electronic component; and
applying a plurality of metallic contacts to the first side of the packaged electronic component.

19. The method of claim 18, further comprising, applying the plurality of polymer contacts to a periphery portion of the first side of the packaged electronic component.

20. The method of claim 19, further comprising, applying the plurality of metallic contacts to a middle portion of the first side of the packaged electronic component.

21. The method of claim 19, further comprising, coating the plurality of polymer contacts and the plurality of metallic contacts with a layer of solder to facilitate attachment of the packaged electronic component to a substrate.

22. The method of claim 19, further comprising, coating the plurality of polymer contacts and the plurality of metallic contacts with a flux layer to facilitate attachment of the packaged electronic component to a substrate.

23. A method for connecting a surface mount package with a substrate, comprising:
employing a surface mount package having a plurality of solder coated polymer balls and a plurality of solder coated copper balls applied thereon;
aligning the solder coated polymer balls and the solder coated copper balls with electrical terminations of a substrate; and
applying heat to the surface mount package and the substrate, such that the heat facilitates connection of the solder coated polymer balls and the solder coated copper balls with the electrical terminations.

24. The method of claim 23, the solder coated polymer balls and the solder coated copper balls absorbing stresses caused by coefficient of thermal expansion (CTE) mismatch, such that the polymer and copper balls mitigate employing an underfill layer.

25. A surface mount package, comprising:
a packaged electronic component;
a plurality of polymer balls placed around a periphery portion of the packaged electronic component; and
a plurality of copper balls placed in a middle portion of the packaged electronic component.

26. The surface mount package of claim 26 employed in a cellular telephone.

27. The surface mount package of claim 26 employed in a computing device.

28. The surface mount package of claim 26 employed in a camera.

29. A surface mount package, comprising:
first means for providing an electrical connection between the surface mount package and a surface, the first means facilitating improved thermal conduction of the package; and
second means for providing an electrical connection between the surface mount package and a surface, the second means facilitating improved mechanical compliance of the package.
